(19) United States
(12) Patent Application Publication
(10) Pub. No.: US 2003/0043950 A1
(43) Pub. Date: Mar. 6, 2003

(54) Phase-locked loop frequency synthesizer with two-point modulation

(76) Inventors: Eric J. Hansen, Moneta, VA (US); William E. Holland, Lynchburg, VA (US)

Correspondence Address: MENDELSOHN AND ASSOCIATES PC, 1515 MARKET STREET, SUITE 715, PHILADELPHIA, PA, 19102, US

(21) Appl. No.: 10/028,850

(22) Filed: Dec. 20, 2001

Related U.S. Application Data
(60) Provisional application No. 60/317,025, filed on Sep. 4, 2001.

(51) Int. Cl. H03D 3/24

(52) U.S. Cl. 375/376

(57) ABSTRACT

A phase-locked loop (PLL) frequency synthesizer having a two-point data modulation scheme and ΣΔ modulator, fractional-N architecture. In the synthesizer, data are modulated at both the PLL frequency divider and the voltage-controlled oscillator (VCO). The complementary frequency responses at these two modulation points allow the PLL bandwidth to be sufficiently narrow to attenuate phase noise from the phase detector, frequency divider, and ΣΔ quantization error, without adversely affecting the data. Fractional-N architecture allows a large range of reference frequencies to be used with the PLL and high frequency resolution of the output signal. The ΣΔ modulator modulates the feedback signal generated by the PLL frequency divider with data and quantizes the spurious signals inherent in a fractional-N design to high frequencies that the PLL loop filter can attenuate.

### CROSS-REFERENCE TO RELATED APPLICATIONS

This applications claims priority from U.S. Provisional Patent Application No. 60/317,025 filed Sep. 4, 2001, and entitled “Bluetooth RF Transceiver.”

### BACKGROUND OF THE INVENTION

1. Field of the Invention

The present invention relates to electronics and, in particular, to phase-locked loops.

2. Description of the Related Art

A frequency synthesizer is an apparatus that generates an output signal having a frequency that is a multiple of an input reference frequency. A common type of frequency synthesizer uses a phase-locked loop (PLL) to generate a periodic output signal that has a constant phase relationship with respect to a periodic input signal.

FIG. 1 shows a schematic block diagram of a PLL 100 of the prior art. PLL 100 includes a phase detector 102, a loop filter 104, a voltage-controlled oscillator (VCO) 106, and a feedback path having a frequency divider 108. A periodic reference signal 110 of frequency F_{ref} is fed to phase detector 102 together with feedback signal 112 (the output of frequency divider 108). The output of phase detector 102 is a pulse that is related to the phase difference between reference signal 110 and feedback signal 112. The output of phase detector 102 is filtered through loop filter 104 and fed to VCO 106. Due to the feedback in the PLL, the frequency Fₒᵤₜ of output signal 114 of VCO 106 is driven to equal the reference frequency F_{ref} multiplied by the division factor N of frequency divider 108 according to Equation (1) as follows:

Fₒᵤₜ=N F_{ref} (1)

Phase detector 102 of PLL 100 is a circuit that typically generates high levels of transient noise at F_{ref}, its frequency of operation. This noise is superimposed on the output voltage of the phase detector and can modulate the VCO frequency output accordingly. To prevent this, loop filter 104 should have an appropriately narrow bandwidth.

In a typical implementation of PLL 100, the frequency divider divides the frequency of the VCO output signal 114 by a selected integer in order to generate the frequency-divided feedback signal that is supplied to the phase detector. The difference in phase between frequency-divided feedback signal 112 and reference signal 110 is output from the phase detector and applied to the loop filter and the VCO in a manner that causes output signal 114 to change in frequency such that the phase error between the frequency-divided feedback signal and the reference signal is minimized. With an integer division factor, the output frequency step size (also referred to as the RF channel spacing) is constrained to be equal to the reference signal frequency.

A common technique used to synthesize output signals having a frequency that is a rational (i.e., non-integer) multiple of the reference frequency is referred to as fractional-N PLL frequency synthesis. To implement this technique, programmable frequency dividers capable of effectively dividing by non-integers have been developed. This function is accomplished by adding internal circuitry that enables the division factor to change dynamically. For example, if the division factor is switched between N and N+1 in a given proportion, an average division factor can be realized that is N+K/M, where N, K, and M are integers and K<M. Using this technique, a channel spacing equal to a fraction of the reference frequency, e.g., F_{ref}/M, can be obtained.

A problem common to many of the known PLL circuits, both integer and fractional-N, is that they do not lend themselves to a relatively simple and practicable way of generating an output signal, such as signal 114 of PLL 100, that is modulated with data. The primary problem revolves around the fact that the PLL tends to process the modulation as error that it tries to correct, resulting in distortion of the desired modulation. A long patent history testifies to the work that has been invested in attempting to effectively solve this problem, the net result of which work has been only a partial success.

For example, U.S. Pat. No. 6,011,815 (Eriksson et al.), the teachings of which are incorporated herein by reference, teaches a phase modulation technique based on using a ΣΔ modulator (also often referred to as sigma-delta, delta-sigma, or ΣΔ modulator) to control the division factor of a fractional-N PLL. One problem with this PLL architecture is attenuation of data due to the narrow PLL bandwidth. However, increasing the bandwidth is not desirable due to the higher levels of phase detector and ΣΔ modulator quantization noise that would pass through the loop filter and interfere with data transmission.

### SUMMARY OF THE INVENTION

The present invention provides a phase-locked loop (PLL) frequency synthesizer having a two-point data modulation scheme and ΣΔ modulator, fractional-N architecture. In the synthesizer, data are modulated at both the PLL frequency divider and the voltage-controlled oscillator (VCO). The complementary frequency responses at these two modulation points allow the PLL bandwidth to be sufficiently narrow to attenuate phase noise from the phase detector, frequency divider, and ΣΔ quantization error, without adversely affecting the data. Fractional-N architecture allows a large range of reference frequencies to be used with the PLL and high frequency resolution of the output signal. The ΣΔ modulator modulates the feedback signal generated by the PLL frequency divider with data and quantizes the spurious signals inherent in a fractional-N design to high frequencies that the PLL loop filter can attenuate.

According to one embodiment, the present invention is a frequency synthesizer for generating a data-modulated output signal based on a reference signal and an input data signal, the frequency synthesizer comprising: (a) a phase-locked loop (PLL) circuit configured to receive the reference signal and generate the data-modulated output signal; (b) a first data-modulation path configured to (i) generate a first data-modulated input signal based on the input data signal and (ii) apply the first data-modulated input signal at a voltage-controlled oscillator (VCO) of the PLL circuit; and (c) a second data-modulation path configured to (i) generate a second data-modulated input signal based on the input data signal and (ii) apply the second data-modulated input signal at a frequency divider of the PLL circuit.

### BRIEF DESCRIPTION OF THE DRAWINGS

Other aspects, features, and advantages of the present invention will become more fully apparent from the following detailed description, the appended claims, and the accompanying drawings in which:

FIG. 1 is a schematic block diagram of a PLL of the prior art;

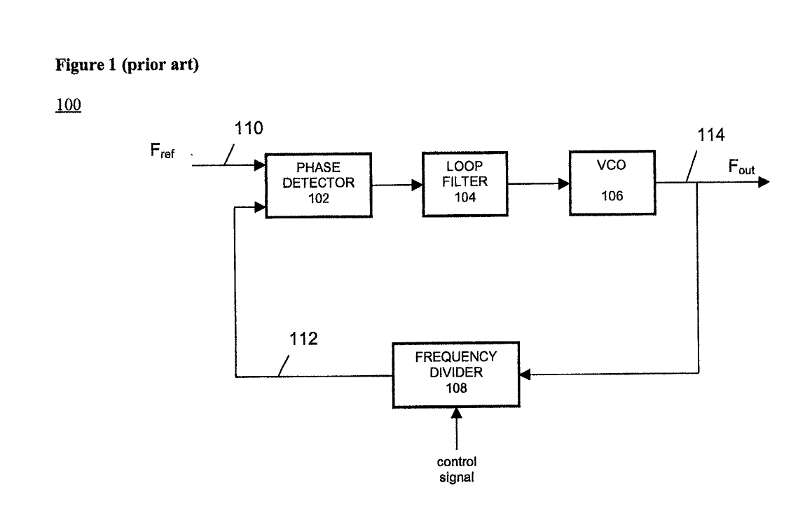

FIG. 2 shows a schematic block diagram of a PLL frequency synthesizer according to one embodiment of the present invention;

FIGS. 3A-C show a schematic block diagram of a Gaussian low-pass filter that may be used in the synthesizer of FIG. 2 and its look-up tables for two representative baseband frequencies of 12 and 13 MHz according to one embodiment of the present invention;

FIGS. 4A-B show schematic block diagrams for two implementations of a digital-to-analog converter that may be used in the synthesizer of FIG. 2;

FIG. 5 shows a schematic block diagram of a tank circuit of one implementation of the VCO that may be used in the synthesizer of FIG. 2;

FIGS. 6A-B illustrate the operation of a scaling block that may be used in the synthesizer of FIG. 2 and its representative look-up table of scale values according to one embodiment of the present invention;

FIGS. 7A-C illustrate the operation of a carrier selection block that may be used in the synthesizer of FIG. 2, a method for the carrier value calculation, and a representative look-up table for the method according to one embodiment of the present invention;

FIG. 8 shows a schematic block diagram of a ΣΔ modulator that may be used in the synthesizer of FIG. 2 according to one embodiment of the present invention; and

FIG. 9 shows a schematic block diagram of a frequency divider that may be used in the synthesizer of FIG. 2 according to one embodiment of the present invention.

### DETAILED DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments mutually exclusive of other embodiments. Although the invention is particularly suitable for a portable communication device, such as a Bluetooth RF transceiver, those skilled in the art can appreciate that the invention can be equally applied to other devices.

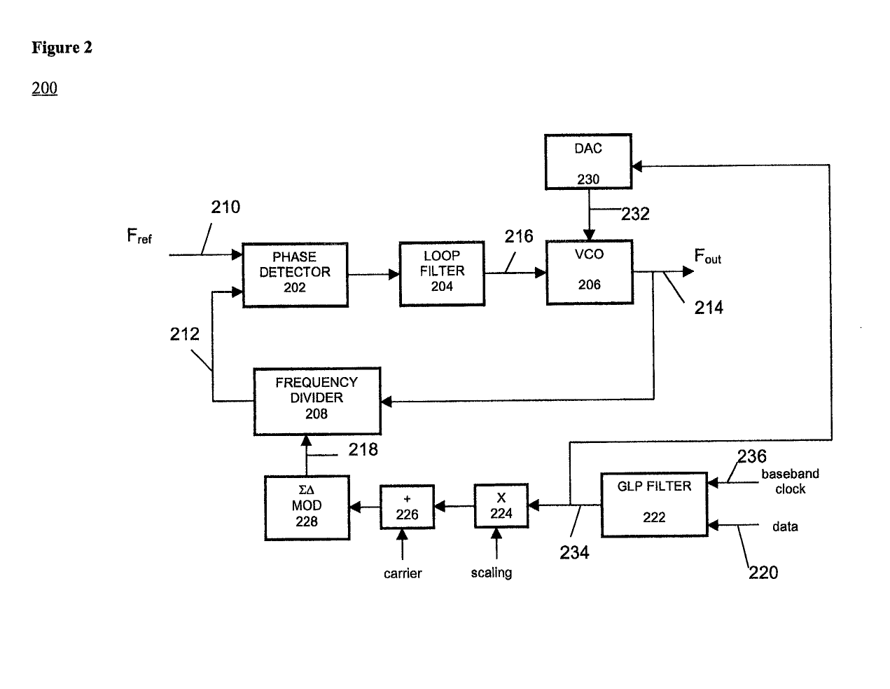

FIG. 2 shows a schematic block diagram of a PLL frequency synthesizer 200 according to one embodiment of the present invention. Synthesizer 200 comprises a phase detector 202, a loop filter 204, a VCO 206, and a feedback path having a frequency divider 208. These elements of synthesizer 200 form a PLL. A periodic reference signal 210 of frequency F_{ref} is fed to phase detector 202 together with a feedback signal 212 (the output of frequency divider 208). The output of phase detector 202 is filtered through loop filter 204 to produce signal 216. Signal 216 is then fed to VCO 206, the output of which (an output signal 214) is fed back to frequency divider 208. The division factor of frequency divider 208 is controlled by a control signal 218. Synthesizer 200 is preferably implemented to support a multitude of reference frequencies. In one embodiment, these reference frequencies are about 12.00, 12.60, 12.80, 13.00, 14.40, 15.36, 16.80, 19.20, 19.44, 19.68, 19.80, and 26.00 MHz. Loop filter 204 is preferably implemented as a passive, two-pole filter with a closed-loop bandwidth approximately in the 30-kHz range.

Synthesizer 200 comprises additional circuitry for generating output signal 214 that is modulated based on a data signal 220. This circuitry includes a Gaussian low-pass filter 222, a scaling block 224, a carrier selection block 226, a ΣΔ modulator 228, and a digital-to-analog converter (DAC) 230, possible implementations of each of which will be described below. In a preferred embodiment, synthesizer 200 implements a two-point modulation scheme that applies modulation at the input to ΣΔ modulator 228 and at VCO 206 via an input signal 232. Blocks 224 and 226 and modulator 228 form the ΣΔ data modulation path. DAC 230 forms the VCO data modulation path.

Prior to being modulated by the PLL via either path, data 220 are passed through filter 222 to produce signal 234. Signal 234 is fed to both DAC 230 and block 224. Signal 234 is scaled in block 224, carrier frequency-injected in block 226, and then processed in ΣΔ modulator 228 to produce signal 218. Signal 218 is used in divider 208 to control its division factor N. The output of DAC 230 (signal 232) is summed in VCO 206 with the output of loop filter 204 (signal 216) and the sum is used in VCO 206 for generating data-modulated output signal 214.

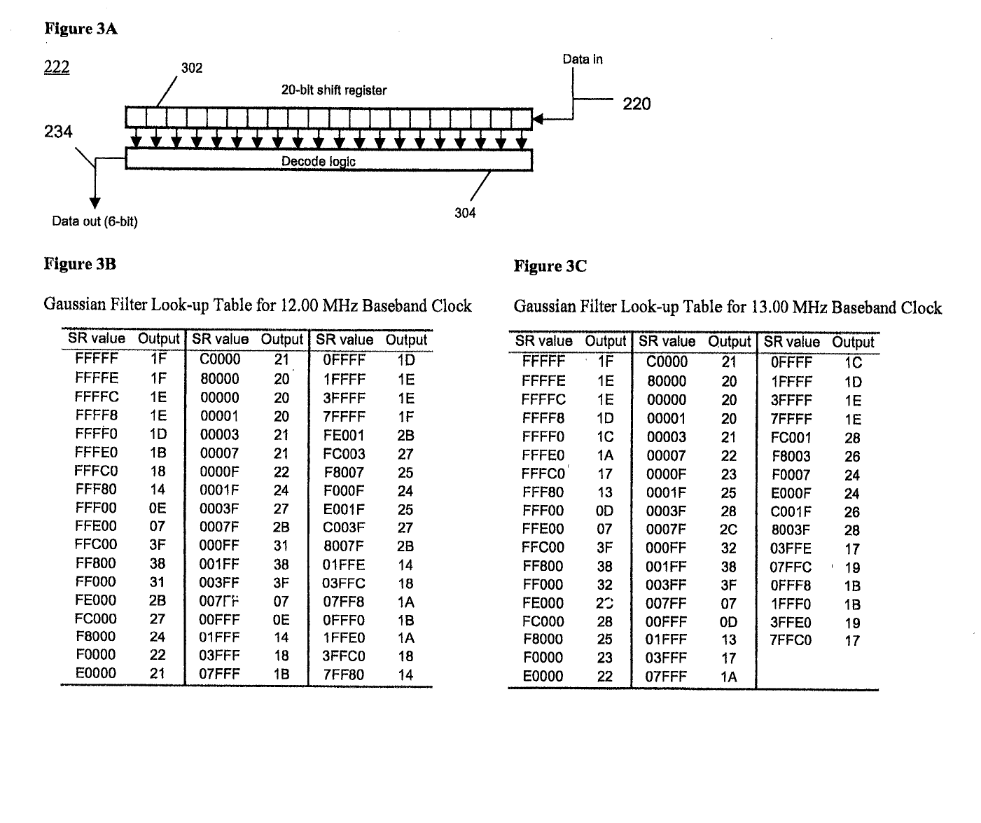

FIG. 3A shows a schematic block diagram of one implementation of Gaussian low-pass filter 222 of synthesizer 200. In one embodiment, filter 222 is implemented using a ROM look-up logic and comprises a 20-bit shift register (SR) 302 and a decoding logic block 304. The data fed into filter 222 (signal 220 in FIG. 2) are oversampled using an external baseband clock signal 236 (in FIG. 2). In a preferred embodiment, baseband clock signal 236 for filter 222 and reference signal 210 for phase detector 202 are both supplied by the same source. Register 302 stores a portion of the oversampled 1-bit data stream. Every clock cycle, decoding logic block 304 transforms the 20 bits of data stored in register 302 into a 6-bit output (signal 234 in FIG. 2) using a look-up table. Signal 234 serves as an input to both DAC 230 and scaling block 224. In one embodiment, filter 222 implements 12×-oversampling and signal 236 is 12.00 MHz in frequency. In another embodiment, filter 222 implements 13×-oversampling and signal 236 is 13.00 MHz in frequency. Representative look-up tables for these two embodiments are shown in FIGS. 3B and 3C, respectively. The 54 different SR values listed in FIG. 3B represent the 54 different possible bit patterns when 1-bit data are shifted through a 20-bit register with 12×-oversampling. The same is true for the 52 different SR values listed in FIG. 3C for 13×-oversampling. In these illustrative embodiments, filter 222 has a corner frequency (defined as the frequency at which the filter's transfer function is −3 dB) of approximately 500 kHz. Employing different oversampling rates, baseband frequencies, and/or look-up tables will result in different corner frequencies for filter 208.

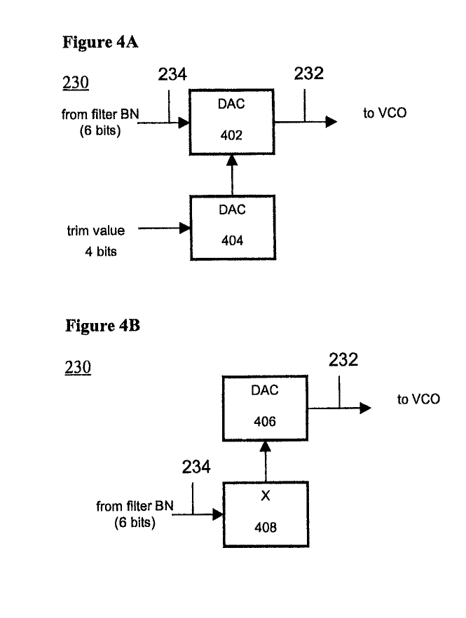

FIG. 4A shows a schematic block diagram of one implementation of DAC 230 of synthesizer 200. DAC 230 comprises a 6-bit DAC 402 and a 4-bit DAC 404. Adjustment of the gain of DAC 230 is achieved by using a multiplying DAC configuration for DAC 402. Filtered data from filter 222 (signal 234 in FIG. 2) are applied to one input of DAC 402. The adjustable output of DAC 404 applied at another input of DAC 402 serves as the reference voltage for DAC 402. The output of DAC 404 can be adjusted using a variable trim value applied to DAC 404. This offers the ability to adjust the gain of DAC 230 and, therefore, the VCO data modulation path of synthesizer 200 by changing the trim value.

FIG. 4B shows a schematic block diagram of another implementation of DAC 230 of synthesizer 200 to provide adjustable gain in the VCO data modulation path. Instead of using the multiplying DAC configuration of FIG. 4A, a digital multiplier 408 is incorporated into DAC 230 prior to a 6-bit DAC 406. The gain of multiplier 408 is tuned, e.g., manually, to achieve the desired gain for DAC 230 and, therefore, the VCO data modulation path.

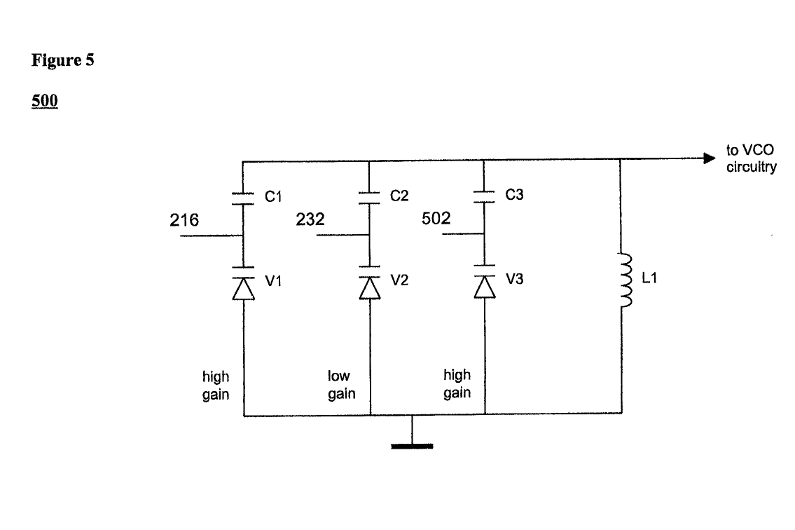

FIG. 5 shows a schematic block diagram of a tank circuit 500 of one implementation of VCO 206 of synthesizer 200. Tank circuit 500 comprises four parallel circuit paths: one path comprising an inductor L1 and two or more gain paths, each comprising a capacitor in series with a varactor. A first high-gain path comprises capacitor C1 in series with varactor V1, where signal 216 from loop filter 204 of FIG. 2 is applied between capacitor C1 and varactor V1. A low-gain path comprises capacitor C2 in series with varactor V2, where signal 232 from DAC 230 of FIG. 2 is applied between capacitor C2 and varactor V2. An optional high-gain path comprises capacitor C3 in series with varactor V3, where a third modulation signal 502 is applied between capacitor C3 and varactor V3.

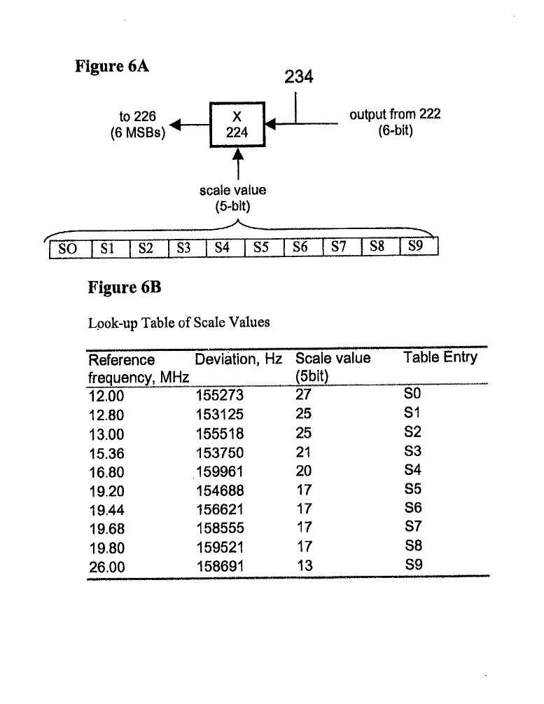

FIG. 6A shows a schematic block diagram of one implementation of scaling block 224 of synthesizer 200. Scaling block 224 scales the frequency deviation due to data modulation fed to the PLL through frequency divider 208 to be in a preferred frequency range. Block 224 receives a 6-bit input from filter 222 (signal 234 in FIG. 2) and multiplies it by a 5-bit scale value chosen from a look-up table of scale values to obtain an 11-bit product. The six most significant bits (MSB) of the product are output from block 224 to carrier selection block 226. Different 5-bit scale values are preferably applied for different reference frequencies to keep the frequency deviation within the preferred frequency range. FIG. 6B shows a table of ten 5-bit scale values S0-S9 according to one embodiment, wherein the frequency deviation is approximately 15 to 16 kHz.

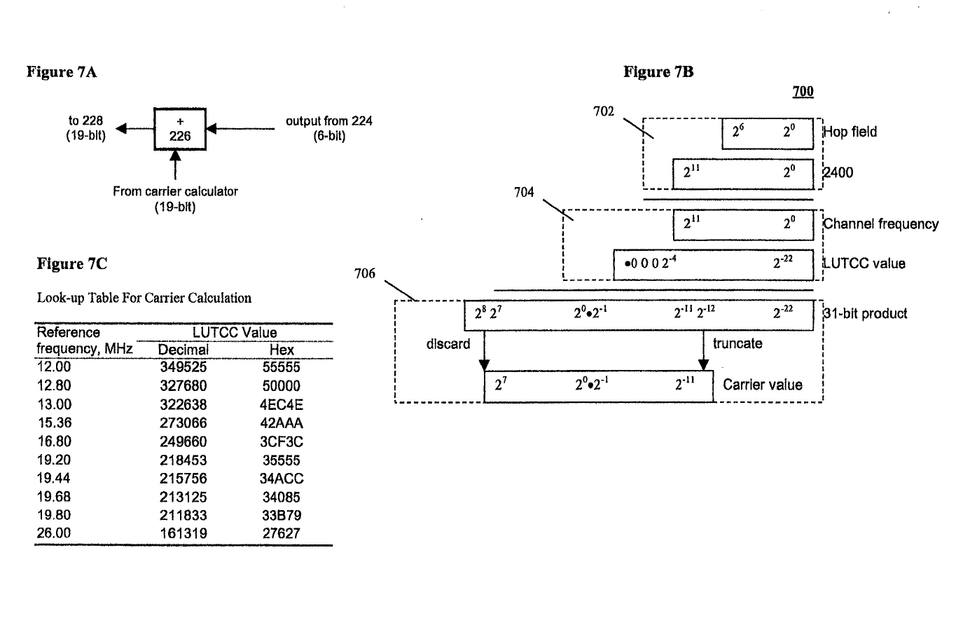

FIG. 7A shows a schematic block diagram of one implementation of carrier selection block 226 of synthesizer 200. Carrier selection block 226 serves to select an output RF channel of synthesizer 200, within which data-modulated output signal 214 is transmitted. To select a data-modulated frequency within the channel, the carrier value corresponding to the channel frequency is added to the output of scaling block 224. The sum is output from block 226 to ΣΔ modulator 228.

FIG. 7B illustrates a method 700 for the carrier value calculation, which carrier value is used in block 226, according to one embodiment of the present invention. According to method 700, the carrier value is a 19-bit binary number in 8.11 format corresponding to a synthesizer output channel frequency in the range between 2400 and 2500 MHz. This 19-bit number is calculated as follows. The selected output channel is specified in the 7-bit Hop field as a frequency offset from 2400 MHz. In step 702 of method 700, the number in the Hop field is added to 2400 to obtain a 12-bit channel frequency. In step 704, the 12-bit channel frequency is multiplied by a 19-bit value from a look-up table for carrier calculation (LUTCC) to obtain a 31-bit product. In step 706, the MSB and the 11 least significant bits (LSB) of the product are dropped to obtain the 19-bit carrier value.

FIG. 7C shows an LUTCC that may be used in method 700 according to one embodiment of the present invention. The LUTCC value used in step 704 of method 700 depends on the employed reference frequency and represents the period of the reference signal. For reference frequencies between 12.00 and 26.00 MHz, the three MSBs of the LUTCC values are all zero. Therefore, these bits need not be stored in the LUTCC. Both decimal and hexadecimal representations of the 19-bit LUTCC values are given in FIG. 7C. For channel frequencies between 2400 and 2500 MHz and the LUTCC values of FIG. 7C, the MSB of the 31-bit product obtained in step 704 of method 700 is always zero and, therefore, may be dropped in step 706. To obtain higher precision of the carrier value, the precision of the LUTCC values used in method 700 can be increased, for example, to 23 bits.

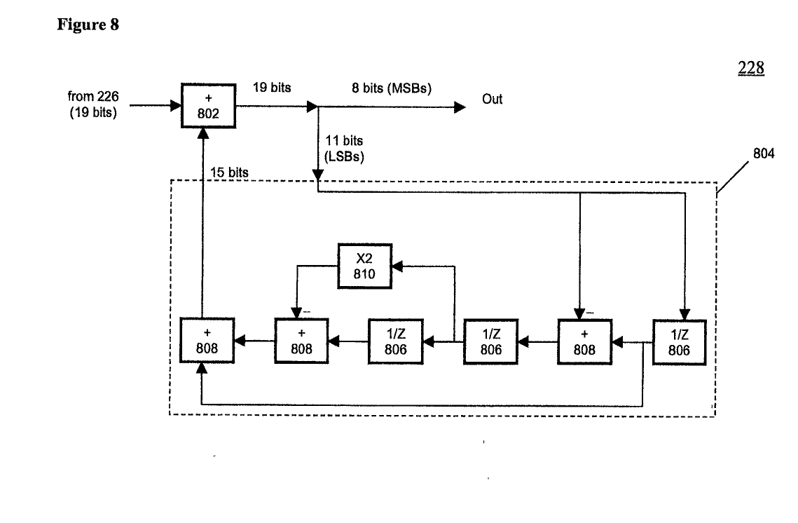

FIG. 8 shows a schematic block diagram of one implementation of ΣΔ modulator 228 of synthesizer 200. Modulator 228 comprises an adder 802 and a noise-shaping loop 804. A 19-bit output value from block 226 of FIG. 2 is summed with a 15-bit output value of loop 804 in adder 802. In a preferred embodiment, the ranges of the values generated by block 226 and loop 804 are such that the sum does not overflow to the 20th bit. A 19-bit output value of adder 802 is split into 8 MSBs and 11 LSBs. The 8 MSBs are output from modulator 228 to divider 208 of FIG. 2. The 11 LSBs are fed back to loop 804. Loop 804 comprises a series of delay elements (1/Z) 806 and adders (+) 808, and a multiply-by-two element (×2) 810. In one embodiment of the present invention, delay elements 806 are implemented as latches clocked by the reference frequency and multiply-by-two element 810 is implemented as a shift register, which appends an extra LSB to the input value (i.e., implements a logical shift left).

ΣΔ modulator 228 has three main functions: (1) it sets the fractional-N value for frequency divider 208 to achieve the desired PLL output frequency, (2) it modulates feedback signal 212 with data, and (3) it quantizes spurious signals to high frequencies that loop filter 204 can attenuate. In the implementation shown in FIG. 8, modulator 228 may be thought of as a quantizer with quantization error fed back into the quantizer via noise-shaping loop 804. Modulator 228 is a third-order modulator implementing a single truncation operation. It has advantages over ΣΔ modulators of the prior art, e.g., MASH structures implementing multiple truncation operations. (A typical MASH structure utilizes a series of one-bit oversampling data converters, each of which performs a partial noise-shaped conversion and then passes the conversion error onto the next stage. The individual outputs of the data converters are combined to form a composite output of the structure.) In particular, the single truncation performed by modulator 228 produces less quantization error than do the multiple truncations of the prior art MASH modulators. Also, no integrators are present in modulator 228, which effectively eliminates problems of accumulator saturation or overflow common for the prior art MASH modulators.

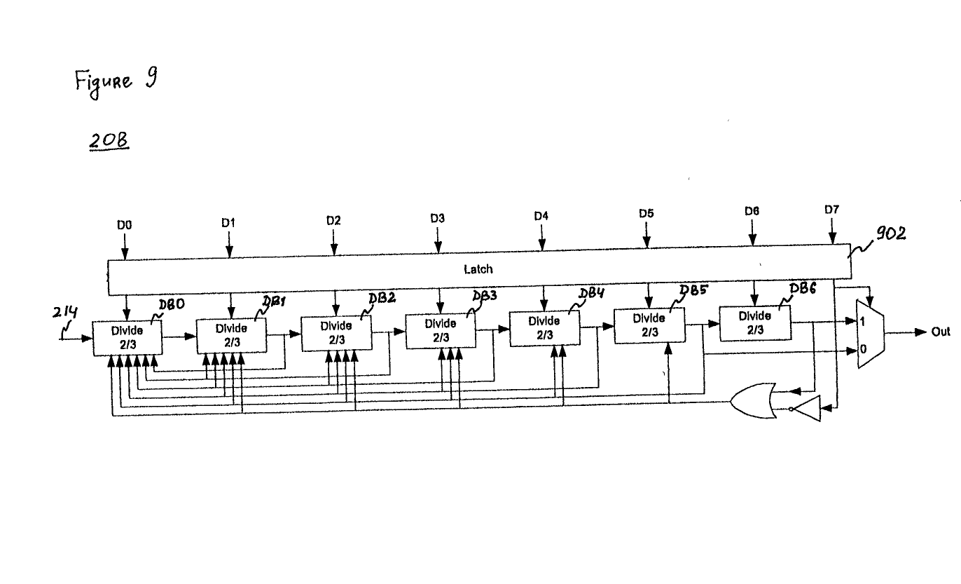

FIG. 9 shows a schematic block diagram of one implementation of frequency divider 208 of synthesizer 200. Divider 208 comprises a latch 902 and a series of seven divide blocks DB0-6. Block DB0 receives analog VCO output signal 214 and generates a digital frequency-divided signal. Each subsequent block DB1-6 receives a digital frequency-divided signal from the preceding block DB and generates a next digital frequency-divided signal. In one embodiment, each divide block DB is configured to perform frequency division by two or three depending on the state of its control inputs. To generate a digital control signal, the instant output signal of each divide block DB is compared to a threshold value. If the output signal is above the threshold value, the corresponding control signal is set to one. If the output signal is less then the threshold value, the corresponding control signal is set to zero. If all control inputs to block DB are set to one, division by three is performed by skipping one input pulse. If one control input to block DB is set to zero, division by two is performed. The digital frequency-divided signal generated by each block DB1-6 is used as a control signal in each of the preceding blocks DB. For example, the digital frequency-divided signal generated by block DB5 is used as a control signal in blocks DB0-4, the digital frequency-divided signal generated by block DB4 is used as a control signal in blocks DB0-3, etc.

In addition to digital frequency-divided signals from blocks DB1-6, the 8-bit output of modulator 228 (signal 218 in FIG. 2) is also used to generate control signals for blocks DB0-6. Prior to being input to divide blocks DB0-6, the 8-bits (D0-D7) of signal 218 are latched onto latch 902. Then, each divide block DB0-6 uses the corresponding bit (D0-D6) on latch 902 as its control input.

When the MSB in the output of modulator 228 is set to logic 0 (D7=0), the last divide block DB6 in the series is bypassed and output signal 212 is generated using six divide blocks DB0-5. When D7=1, all seven divide blocks DB0-6 are used. In the described embodiment of divider 208, a division factor range of 64 to 255 is realized. When D7=1, the accessible range of division factors for divider 208 is from 128 to 255. When D7=0, the range of division factors for divider 208 becomes 64 to 127. Different ranges of division factors for divider 208 may be realized in a similar fashion by using a different number of divide blocks DB and/or by configuring blocks DB for division by integers other than 2 or 3.

Data applied to the PLL via the ΣΔ data modulation path are subjected to an effective low-pass frequency response set by the corner frequency of loop filter 204. Data applied to the PLL via the VCO data modulation path are subjected to an effective high-pass frequency response, again set by the corner frequency of loop filter 204. The corresponding PLL transfer functions for these two data modulation paths, G_{N} for the ΣΔ data modulation path and G_{VCO} for the VCO data modulation path, are given by Equations (2) and (3) as follows:

$$\begin{matrix}{G}_{N} = \frac{{K}_{pd} {K}_{VCO} {H}_{LF}}{sN + {K}_{pd} {K}_{VCO} {H}_{LF}} & ( 2 ) \\ {G}_{VCO} = \frac{{sNK}_{mod} K}{sN + {K}_{pd} {K}_{VCO} {H}_{LF}} & ( 3 )\end{matrix}$$

where K_{pd} is the phase detector gain; K_{VCO} is the VCO gain when input 216 (in FIG. 2) is used; K_{mod} is the gain for the VCO data modulation path (i.e., the combined gain of DAC 230 and the VCO when input 232 (in FIG. 2) is used); K is a tuning coefficient depending on all three gains; and H_{LF} is the loop filter closed-loop transfer function. When K_{mod} K≈1, the frequency response of synthesizer 200 for transmission of data determined by the sum of Equations (2) and (3) is essentially constant up to approximately the corner frequency of PLL loop filter 204. Setting the value of K_{mod} K to 1 can be implemented, e.g., by adjusting the trim value applied to DAC 404 of DAC 230 as previously described in the context of FIG. 4A. The resulting complementary transfer functions for the two data modulation paths allow the PLL bandwidth to be sufficiently narrow to attenuate phase noise without adversely affecting transmission of data.

Alternative Embodiments

Embodiments of the present invention, as described above, provide a PLL-based frequency synthesizer having two modulation points: (1) at the feedback frequency divider (e.g., divider 208 of FIG. 2) and (2) at the VCO (e.g., VCO 206 of FIG. 2). Other configurations of frequency synthesizers employing PLLs may have a reference frequency divider placed at the reference frequency input of the phase detector (e.g., input 210 of phase detector 202 in FIG. B) in addition to the feedback frequency divider. In such configurations, a modulation point could be implemented at the reference frequency divider instead of or in addition to the modulation point at the feedback frequency divider. Consequently, a similar ΣΔ data modulation path could be implemented to generate the control signal for the reference frequency divider. An embodiment with data modulation at both the feedback frequency divider and the reference frequency divider, in addition to the modulation at the VCO, would then have three modulation points, with two different ΣΔ modulators being used to generate control signals for the two frequency dividers.

Both the feedback frequency divider and the optional reference frequency divider may be implemented as described in the context of FIG. 9. Alternatively, different implementations of frequency dividers may be used, such as, for example, one described in U.S. Pat. No. 6,008,703 by Perrott, et al., without departing from the principles of data modulation described in this specification.

Gaussian low-pass filter 222 of synthesizer 200 of FIG. 2 serves the purpose of implementing a Gaussian Frequency Shift Keying (GFSK) modulation method, e.g., for Bluetooth frequency synthesizers. Other modulation methods, e.g., Quadrature Phase Shift Keying (QPSK), Quadrature Amplitude Modulation (QAM), or Time Shift Keying (TSK), may be implemented for other types of frequency synthesizers. Consequently, an alternative type of low-pass filter corresponding to the modulation method employed in a particular embodiment (or even no low-pass filter) may be used in place of filter 222 without departing from the principles of data modulation described in this specification.

Scaling block 224 and carrier selection block 226 of synthesizer 200 of FIG. 2 are included in a preferred embodiment, which is designed to operate using multiple different reference frequencies, e.g., those listed in the tables of FIGS. 6B and 7C. Frequency synthesizers intended to operate with only a single reference frequency may be implemented without scaling block 224 and/or carrier selection block 226.

In one embodiment of the present invention, the VCO (e.g., VCO 206 of FIG. 2) could be a digital VCO. In that case, a DAC (e.g., DAC 230 of FIG. 2) would not be necessary to convert digital signals (e.g., signal 234 of FIG. 2) into the analog domain.

Although the present invention has been described in the context of specific implementations for various components, those skilled in the art will understand that other implementations may be used for other embodiments of the present invention. For example, sigma-delta modulator 228 of FIG. 2 may be implemented using configurations different from that shown in FIG. 8, such as those based on MASH architecture.

In general, different embodiments or implementations of the present invention may yield one or more of the following advantages. One advantage of the invention is that a combination of ΣΔ modulation at a frequency divider and narrow bandwidth loop filter reduces phase noise at the VCO. Another advantage is that the two-point modulation scheme allows data to be transmitted without unlocking the PLL and without significant distortion of the data.

In general, embodiments of the present invention may be implemented for PLL frequency synthesizers operating in various frequency ranges. Also, an integer-N PLL frequency divider, instead of a fractional-N PLL frequency divider, may be used in some embodiments of the present invention. Similarly, different binary widths for data, scaling and carrier values, and/or ΣΔ fractionality may be implemented.

While this invention has been described with reference to illustrative embodiments, this description is not intended to be construed in a limiting sense. Various modifications of the described embodiments, as well as other embodiments of the invention, which are apparent to persons skilled in the art to which the invention pertains are deemed to lie within the principle and scope of the invention as expressed in the following claims.

What is claimed is:

1. A frequency synthesizer for generating a data-modulated output signal based on a reference signal and an input data signal, the frequency synthesizer comprising:
(a) a phase-locked loop (PLL) circuit configured to receive the reference signal and generate the data-modulated output signal;
(b) a first data-modulation path configured to (i) generate a first data-modulated input signal based on the input data signal and (ii) apply the first data-modulated input signal at a voltage-controlled oscillator (VCO) of the PLL circuit; and
(c) a second data-modulation path configured to (i) generate a second data-modulated input signal based on the input data signal and (ii) apply the second data-modulated input signal at a frequency divider of the PLL circuit.

2. The invention of claim 1, wherein the first and second data-modulated input signals have substantially complementary frequency responses.

3. The invention of claim 1, wherein:
the PLL circuit comprises a phase detector, a loop filter connected to the phase detector, the VCO connected to the loop filter, and the frequency divider, which is part of a feedback path connecting the VCO and the phase detector.

4. The invention of claim 3, wherein:
the first data-modulation path has a high-pass frequency response corresponding substantially to a corner frequency of the loop filter; and
the second data-modulation path has a low-pass frequency response corresponding substantially to the corner frequency of the loop filter.

5. The invention of claim 3, wherein:
the phase detector is configured to generate a phase-difference signal based on the reference signal and a frequency-divided signal from the frequency divider;
the loop filter is configured to generate a loop-filtered signal based on the frequency-divided signal from the phase detector;
the VCO is configured to generate the data-modulated output signal based on the loop-filtered signal from the loop filter and the first data-modulated input signal from the first data modulation path; and
the frequency divider is configured to generate the frequency-divided signal based on the data-modulated output signal from the VCO and the second data-modulated input signal from the second data modulation path, wherein the second data-modulated input signal determines a division factor applied by the frequency divider to the data-modulated output signal to generate the frequency-divided signal.

6. The invention of claim 1, wherein the second data modulation path comprises a sigma-delta modulator configured to generate the second data-modulated input signal based on the input data signal.

7. The invention of claim 6, wherein frequency synthesizer is configured to operate with two or more different reference signals and the second data modulation path further comprises:
a scaling block configured to adjust gain of the second data modulation path based on a selected reference signal; and
a carrier-selection block configured to inject a carrier frequency based on the selected reference signal.

8. The invention of claim 6, wherein the frequency synthesizer applies Gaussian frequency shift keying (GFSK) data modulation and the input data signal is Gaussian low-pass filtered prior to application to the first and second data modulation paths.

9. The invention of claim 6, wherein the sigma-delta modulator quantizes spurious signals to high frequencies that are attenuated within the PLL circuit.

10. The invention of claim 6, wherein the sigma-delta modulator comprises:
(i) an adder; and
(ii) a noise-shaping loop, wherein:
the adder is configured to generate a summation signal based on the input data signal and an output signal from the noise-shaping loop, wherein:
a set of one or more most significant bits (MSBs) of the summation signal corresponds to the second data-modulation input signal applied to the frequency divider; and
a set of one or more least significant bits (LSBs) of the summation signal is fed back as an input signal to the noise-shaping loop.

11. The invention of claim 10, wherein the sigma-delta modulator functions as a quantizer with quantization error fed back into the quantizer via the noise-shaping loop.

12. The invention of claim 1, wherein the VCO is an analog VCO, the first data-modulated input signal is an analog signal, and the first data modulation path comprises a digital-to-analog converter (DAC) to generate the analog first data-modulated input signal.
